(19) United States
(12) Patent Application Publication
(10) Pub. No.: US 2011/0139237 A1
(43) Pub. Date: Jun. 16, 2011

(54) PHOTOVOLTAIC CELL, AND SUBSTRATE FOR SAME

(75) Inventor: Emmanuelle PETER, Aix en Provence (FR)

(73) Assignee: SAINT-GOBAIN GLASS FRANCE, Courbevoie (FR)

(21) Appl. No.: 12/958,569

(22) Filed: Dec. 2, 2010

Related U.S. Application Data
(63) Continuation of application No. PCT/FR2009/050984, filed on May 27, 2009.
Application No. PCT/FR2009/050984 is a continuation of application No. 12/171,691, filed on Jul. 11, 2008.

(30) Foreign Application Priority Data
Jun. 2, 2008 (FR) 0853601

(51) Int. Cl. H01L 31/0224

(52) U.S. Cl. 136/256

(57) ABSTRACT

The invention relates to a photovoltaic cell having an absorbent photovoltaic material, especially one based on cadmium, said cell comprising a faceplate substrate, especially a transparent glass substrate, having, on a main surface, a transparent electrode coating consisting of a thin-film multilayer that includes at least one transparent conductive layer, especially one based on optionally doped zinc oxide, characterized in that the electrode comprises at least one smoothing layer.

### CROSS REFERENCES TO RELATED APPLICATIONS

This application is a continuation of International Patent Application No. PCT/FR2009/050984, filed on May 27, 2009, and U.S. patent application Ser. No. 12/171,691, filed Jul. 11, 2008, the disclosures of which are incorporated herein by reference in their entireties. The application claims priority to French Patent Application No. 08 53601, filed Jun. 2, 2008, the disclosure of which is incorporated herein in its entirety.

### BACKGROUND OF THE INVENTION

1. Field of the Invention

The invention relates to a photovoltaic cell faceplate substrate, especially a transparent glass substrate, and to a photovoltaic cell incorporating such a substrate.

2. Discussion of the Background

In a photovoltaic cell, a photovoltaic system having a photovoltaic material which produces electrical energy through the effect of incident radiation is positioned between a backplate substrate and a faceplate substrate, this faceplate substrate being the first substrate through which the incident radiation passes before it reaches the photovoltaic material.

In the photovoltaic cell, the faceplate substrate usually has, beneath a main surface turned toward the photovoltaic material, a transparent electrode coating in electrical contact with the photovoltaic material placed beneath when the main direction of arrival of the incident radiation is considered to be via the top.

This faceplate electrode coating thus constitutes in general the negative terminal of the solar cell.

Of course, the solar cell also has on the backplate substrate an electrode coating that then constitutes the positive terminal of the photovoltaic cell, but in general the electrode coating of the backplate substrate is not transparent.

The material normally used for the transparent electrode coating of the faceplate substrate is in general a material based on a TCO (transparent conductive oxide), such as for example a material based on indium tin oxide (ITO) or based on aluminum-doped zinc oxide (ZnO:Al) or boron-doped zinc oxide (ZnO:B) or gallium-doped or indium-doped or titanium-doped or vanadium-doped zinc oxide (within the context of the invention, in the case of the above compounds based on zinc oxide, the doping is understood to mean for a mass fraction of less than 10%) or else based on fluorine-doped tin oxide (SnO₂:F), or else having mixed indium zinc oxide (IZO), or else based on fluorine-doped tin oxide (SnO₂:F).

These materials are deposited chemically, for example by CVD (chemical vapor deposition), optionally PECVD (plasma-enhanced CVD), or physically, for example by vacuum deposition by cathode sputtering, optionally magnetron sputtering (i.e. magnetically enhanced sputtering).

However, to obtain the desired electrical conduction, or rather the desired low resistance, the TCO-based electrode coating must be deposited with a relatively large physical thickness, of around 500 to 1000 nm and even sometimes higher, this being costly as regards the cost of these materials when they are deposited as thin films.

When the deposition process requires a heat supply, this further increases the manufacturing cost.

It is therefore not possible with electrode coatings having a TCO-based material to independently optimize the conductivity of the electrode coating and its transparency.

The prior art of international patent application WO 2007/092120 teaches a process for manufacturing a solar cell in which the transparent electrode coating consists of a thin-film multilayer deposited on a main face of the faceplate substrate, this coating comprising at least one layer of TCO type based on aluminum-doped zinc oxide (ZnO:Al) or on antimony-doped tin oxide (SnO₂:Sb).

The main drawback of this prior art lies in the fact that the materials are deposited at room temperature using a magnetron sputtering technique, and the layers thus obtained are by nature amorphous or less crystalline than the layers obtained by hot deposition, and therefore of low or moderate electrical conductivity. It is therefore necessary to subject them to a heat treatment, for example of the toughening type, to increase the crystallinity of the layers, which also improves the light transmission.

However, this solution may be further improved.

The prior art also includes U.S. Pat. No. 6,169,246 which relates to a photovoltaic cell having a cadmium-based absorbent photovoltaic material, said cell comprising a transparent glass faceplate substrate having, on a main surface, a transparent electrode coating consisting of a transparent conductive oxide or TCO.

According to that document, a zinc stannate buffer layer is interposed both above the TCO electrode coating and beneath the photovoltaic material, said buffer layer therefore forming neither part of the TCO electrode coating nor part of the photovoltaic material. This layer also has the drawback of being very difficult to deposit by magnetron sputtering techniques, the target incorporating this material being by nature of low conductivity. The use of this type of insulating target in a magnetron sputter coater therefore generates, during sputtering, a large number of arcs causing many defects in the layer deposited.

### SUMMARY OF THE INVENTION

One important object of the invention is to make it possible for charge transfer between the electrode coating and the photovoltaic, particularly cadmium-based, material to be easily controlled and for the efficiency of the cell to be improved as a consequence.

Another important object is also to produce a thin-film-based transparent electrode coating which is simple to produce and as inexpensive as possible to manufacture industrially.

One subject of the invention, in its broadest acceptance, is thus a photovoltaic cell having an absorbent photovoltaic material, especially one based on cadmium, said cell comprising a faceplate substrate, especially a transparent glass substrate, having, on a main surface, a transparent electrode coating consisting of a thin-film multilayer that includes at least one transparent conductive layer, especially one based on optionally doped zinc oxide, and at least one electrically conductive smoothing layer.

In a preferred alternative embodiment of the invention, the transparent conductive layer is based on optionally doped zinc oxide, especially based on aluminum or on boron or on titanium or on indium or on vanadium.

Its physical thickness is preferably between 300 and 900 nm, even more preferably between 400 and 700 nm. The transparent conductive layer is deposited on a tie layer intended to promote the suitable crystalline orientation of the conductive layer deposited on top of it. This tie layer is in particular based on mixed zinc tin oxide or based on mixed indium tin oxide (ITO).

In another preferred alternative embodiment of the invention, the transparent conductive layer is deposited on a layer acting as a chemical diffusion barrier, in particular a barrier to the diffusion of sodium coming from the substrate, and therefore protecting the coating that forms the electrode, and more particularly the conductive layer, especially during an optional heat treatment, especially toughening treatment, the physical thickness of this barrier layer being between 30 and 50 nm.

Preferably, the smoothing layer (between the TCO and the photovoltaic material) is:

based on optionally doped tin oxide SnO₂, such as for example SnO₂:Sb or SnO₂:Al; or

based on a mixed indium tin oxide ITO; or

based on indium oxide InOₓ, on a mixed tin zinc antimony oxide SnₓZn_{y}Sb_{z}Oₓ, on a mixed tin zinc aluminum oxide SnₓZn_{y}Al_{z}O_{w}, which is optionally non-stoichiometric, this oxide being optionally non-stoichiometric.

The doping here means that at least one other metallic element is present in the layer, in an atomic proportion of metals (excluding the element oxygen) ranging from 0.5 to 10%.

A mixed oxide is here an oxide of metallic elements, each metallic element of which is present in an atomic proportion of metals (excluding the element oxygen) of more than 10%.

Thus, the electrode coating must be transparent. It must thus have, when deposited on the substrate, a minimum average light transmission, within the 300-1200 nm wavelength range, of 65% or even 75%, and more preferably 85% and even more especially at least 90%.

If the faceplate substrate has to undergo a heat treatment, especially a toughening treatment, after the thin-film multilayer has been deposited and before it has been integrated into the photovoltaic cell, it is quite possible that, before the heat treatment, the substrate coated with the multilayer acting as electrode coating is not very transparent. For example, the multilayer may have, before this heat treatment, a light transmission in the visible of less than 65% or even less than 50%.

The heat treatment may result not from a toughening operation, but be the consequence of one step in the manufacture of the photovoltaic cell.

Thus, within the context of manufacturing a photovoltaic cell, the functional layer of which, for ensuring energy conversion from light rays to electrical energy, is based on cadmium, its manufacturing process requires a hot deposition phase within a temperature range of between 500 and 700° C. This supply of heat during deposition of the functional layer on the multilayer forming the electrode is sufficient to induce, within this multilayer, physico-chemical transformations leading to the crystalline structure being modified and consequently to the light transmission and the electrical conductivity of the electrode being improved.

It is important for the electrode coating to be transparent before heat treatment, such that it has, after the heat treatment, within the 300 to 1200 nm wavelength range, a minimum average light transmission of 65% or even 75% and more preferably 85% or even more especially at least 90%.

Moreover, within the scope of the invention, the multilayer does not have, in the absolute, the best possible light transmission but does have the best possible light transmission within the context of the photovoltaic cell according to the invention, i.e. within the quantum efficiency QE range of the photovoltaic material in question.

It will be recalled here that the quantum efficiency QE is, as is known, the expression of the probability (between 0 and 1) that an incident photon with a wavelength as abscissa is transformed into an electron-hole pair.

The maximum absorption wavelength λₘ, i.e. the wavelength at which the quantum efficiency is a maximum, is around 600 nm in the case of cadmium telluride.

The transparent conductive layer is preferably deposited in a crystalline form, or in a form which is amorphous but becomes crystalline after heat treatment, on a thin dielectric layer which (then called a “tie layer” as it promotes the suitable crystalline orientation of the metal layer deposited on top of it).

The transparent conductive layer is thus preferably deposited above, or even directly on, an oxide-based tie layer, especially one based on zinc oxide or based on mixed zinc tin oxide, which is optionally doped, possibly with aluminum (the doping is understood, as is usual, to mean a presence of the element in an amount of 0.1 to 10% by molar weight of metallic element in the layer, and the expression “based on” is understood, as is usual, to mean a layer containing predominantly the material; the expression “based on” thus covers the doping of this material by another material), or based on zinc oxide and tin oxide, one or both oxides being optionally doped.

The physical (or actual) thickness of the tie layer is preferably between 2 and 30 nm and more preferably between 3 and 20 nm.

This tie layer is a material which preferably has a resistivity ρ (defined by the sheet resistance of the layer multiplied by its thickness) such that 5 mΩcm<ρ<200 Ω·cm.

The multilayer is generally obtained by a succession of deposition operations carried out by a vacuum technique, such as cathode sputtering, optionally magnetron (magnetically enhanced) sputtering.

The smoothing layer on top of the transparent conductive layer preferably comprises a layer based on a mixed oxide, in particular based on tin oxide, or indium oxide (In₂O₃) or a mixed oxide, in particular based on mixed tin zinc antimony oxide. The physical thickness of this smoothing layer is between 2 and 50 nm. Apart from its smoothing properties, i.e. the smoothing out of the surface of the transparent conductive layer by filling in the spaces resulting from the crystallization of the transparent conductive layer, said smoothing layer also makes it possible to adapt the work function of the electrode.

This smoothing layer also acts as electrical insulation between the front electrode and the functional layer and prevents short circuits between these two layers. It is made of a material which preferably has a resistivity ρ of an order of magnitude higher than the conductive layer such that 5 mΩ·cm<ρ<200 Ω·cm.

The substrate may include a coating based on a photovoltaic material, especially based on cadmium, above the electrode coating, on the side away from the faceplate substrate.

A preferred structure of the faceplate substrate according to the invention is thus of the type: substrate/electrode coating/smoothing layer/photovoltaic material.

It is thus particularly advantageous, when the photovoltaic material is based on cadmium, to choose architectural glazing for vehicle or building applications which is resistant to toughening heat treatment, called “toughenable” glazing or glazing “to be toughened”.

All the layers of the electrode coating are preferably deposited by a vacuum deposition technique, however, it is not excluded for the first layer or layers of the multilayer to be able to be deposited by another technique, for example by a pyrolitic thermal decomposition technique or by CVD, optionally in a vacuum.

Also advantageously, the electrode coating according to the invention may just as well be used as a backplate electrode coating, in particular when it is desired for at least a small portion of the incident radiation to pass completely through the photovoltaic cell.

### BRIEF DESCRIPTION OF THE DRAWINGS

A more complete appreciation of the invention and many of the attendant advantages thereof will be readily obtained as the same become better understood by reference to the following detailed description when considered in connection with the accompanying drawings, wherein:

FIG. 1 illustrates a solar cell faceplate substrate according to the invention according to a first embodiment of the invention, coated with an electrode coating having a transparent conductive oxide;

FIG. 2 illustrates a solar cell faceplate substrate according to a second embodiment of the invention, coated with an electrode coating having a transparent conductive oxide and incorporating a tie layer;

FIG. 3 illustrates a solar cell faceplate substrate according to a third embodiment of the invention, coated with an electrode coating having a transparent conductive oxide and incorporating an alkali-metal barrier layer;

FIG. 4 illustrates a solar cell faceplate substrate according to the invention according to a fourth embodiment of the invention, coated with an electrode coating having a transparent conductive oxide and incorporating both a tie layer and an alkali-metal barrier layer; and

FIG. 5 illustrates a diagram of a photovoltaic cell in cross section.

### DETAILED DESCRIPTION OF THE PREFERRED EMBODIMENTS

In FIGS. 1, 2, 3, 4 and 5, the proportions between the thicknesses of the various coatings, layers and materials have not been strictly respected so as to make them easier to examine.

FIG. 1 illustrates a photovoltaic cell faceplate substrate 10 according to the invention having an absorbent photovoltaic material 200, said substrate 10 having, on a main surface, a transparent electrode coating 100 consisting of a TCO (transparent conductive oxide).

The faceplate substrate 10 is positioned in the photovoltaic cell in such a way that the faceplate substrate 10 is the first substrate through which the incident radiation R passes before reaching the photovoltaic material 200.

The substrate 10 also includes a smoothing layer 22 between the transparent conductive layer 100 and the photovoltaic material 200.

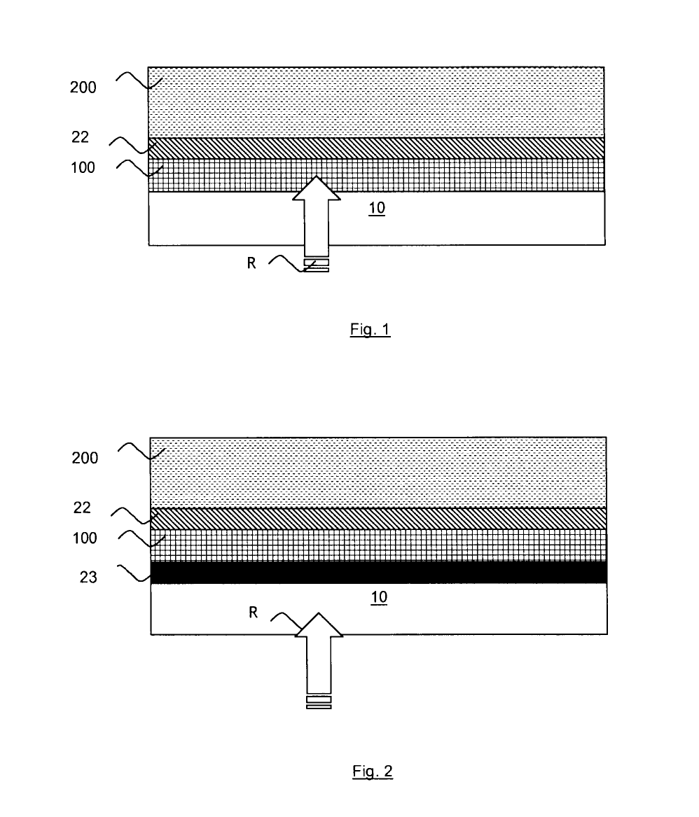

FIG. 2 differs from FIG. 1 by the fact that a tie layer 23 is interposed between the conductive layer 100 and the substrate 10.

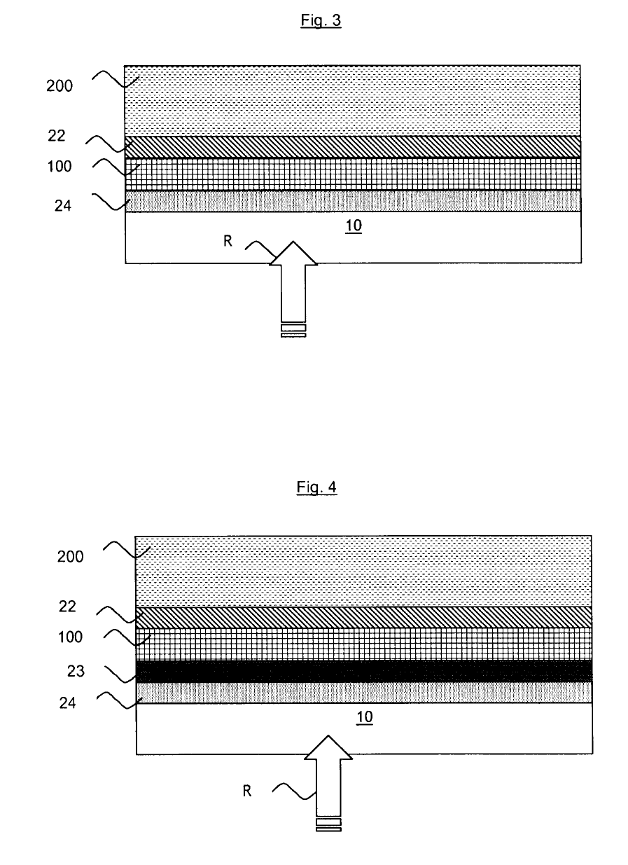

FIG. 3 differs from FIG. 1 by the fact that an alkali-metal barrier layer 24 is interposed between the conductive layer 100 and the substrate 10.

FIG. 4 incorporates the provisions of the solutions given in FIGS. 2 and 3, mainly the fact that the transparent conductive layer is deposited on a tie layer 23 which is itself deposited on an alkali-metal barrier layer 24.

The conductive layer 100, with a thickness of between 500 and 700 nm, is based on aluminum-doped zinc oxide (ZnO:Al). This layer is deposited on a tie layer based on mixed tin zinc oxide, with a thickness of between 2 and 30 nm and more preferably between 3 and 20 nm, for example 7 nm, which is itself deposited on an alkali-metal barrier layer 24, for example based on a dielectric material, especially one based on silicon nitrides, oxides or oxynitrides, or on aluminum nitrides, oxides or oxynitrides, used by themselves or as a mixture, its thickness being between 30 and 50 nm.

The transparent conductive layer 100 is coated with a smoothing layer 22, for example one based on optionally doped tin oxide SnO₂, such as for example SnO₂:Sb or SnO₂:Al, or based on a mixed indium tin oxide ITO, or based on indium oxide InOₓ or else based on a mixed tin zinc antimony oxide SnZnSbOₓ, with a thickness of between 5 and 50 nm.

The functional or photovoltaic layer 200 is based on cadmium telluride.

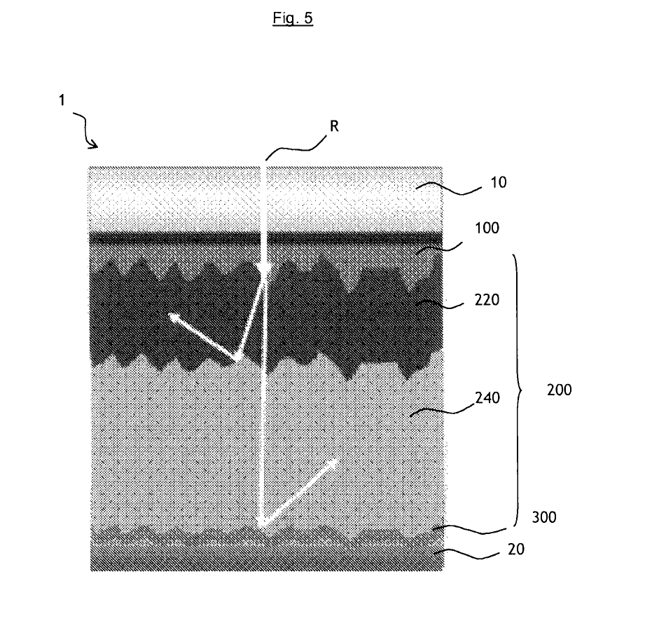

FIG. 5 illustrates a photovoltaic cell 1 in cross section, which is provided with a faceplate substrate 10 according to the invention, through which incident radiation R penetrates, and with a backplate substrate 20.

The photovoltaic material 200, for example of amorphous silicon or crystalline or microcrystalline silicon, or else cadmium telluride or copper indium diselenide (CuInSe₂ or CIS) or copper indium gallium selenium, is located between these two substrates. It consists of a layer of n-doped semiconductor material 220 and a layer of p-doped semiconductor material 240, which layers produce the electric current. The electrode coatings 100, 300, respectively inserted between, on the one hand, the faceplate substrate 10 and the layer of n-doped semiconductor material 220 and, on the other hand, between the layer of p-doped semiconductor material 240 and the backplate substrate 20, complete the electrical structure.

The electrode coating 300 may be based on silver or aluminum, or may also consist of a thin-film multilayer that includes at least one metallic functional layer and is in accordance with the present invention.

Other features of the invention will become apparent in the course of the following descriptions of exemplary embodiments which are given for illustration of the invention and are not intended to be limiting thereof.

### Examples

Example 1 corresponds to an electrode structure known from the prior art, namely glass (extra clear, 3 mm thick)/Si₃N₄ (50 nm)/ZnO:Al (600 nm) in a cadmium-based photovoltaic cell.

The following operating parameters of the cell were obtained:

| Quantum | | | |
|---|---|---|---|
| efficiency | FF (fill factor) | J_{sc} (mA/cm²) | V_{OC} (mV) |
| 8.40% | 60% | 19.7 | 700 |

Example 2 corresponds to an electrode structure according to the invention, namely glass (extra clear, 3 mm thick)/Si₃N₄ (50 nm)/SnZnOₓ:Sb (7 nm)/ZnO:Al (600 nm)/SnZnOₓ:Sb (7 nm) in a cadmium-based photovoltaic cell.

The following operating parameters of the cell were obtained:

| Quantum | | | |
|---|---|---|---|
| efficiency | FF (fill factor) | J_{sc} (mA/cm²) | V_{OC} (mV) |
| 9.90% | 62% | 21 | 762 |

As may be seen, all the operating parameters of the cell are improved with respect to those of the prior art.

The present invention has been described above by way of example. It should be understood that a person skilled in the art is capable of producing various alternative embodiments of the invention without thereby departing from the scope of the patent as defined by the claims.

Obviously, numerous modifications and variations of the present invention are possible in light of the above teachings. It is therefore to be understood that, within the scope of the appended claims, the invention may be practiced otherwise than as specifically described herein.

All patents and other references mentioned above are incorporated in full herein by this reference, the same as if set forth at length.

1. A photovoltaic cell (1) having a cadmium-based absorbent photovoltaic material, said cell comprising a faceplate substrate (10), especially a transparent glass substrate, having, on a main surface, a transparent electrode coating (100) consisting of a thin-film multilayer that includes at least one transparent conductive layer, especially one based on doped zinc oxide, characterized in that the electrode (100) comprises at least one electrically conductive smoothing layer (22) based on tin oxide SnO₂ doped with Al, on a mixed tin zinc antimony oxide SnₓZn_{y}Sb_{z}O_{w} or on a mixed tin zinc aluminum oxide SnₓZn_{y}Al_{z}O_{w}, which is optionally non-stoichiometric.

2. The photovoltaic cell (1) as claimed in claim 1, characterized in that it includes at least one tie layer (23) between the substrate (10) and the transparent conductive layer (100).

3. The photovoltaic cell (1) as claimed in claim 2, characterized in that the tie layer (23) is based on zinc oxide or based on mixed zinc tin oxide or based on mixed indium tin oxide (ITO).

4. The photovoltaic cell (1) as claimed in claim 1, characterized in that it includes at least one alkali-metal barrier layer (24) between the substrate (10) and the transparent conductive layer (100).

5. The photovoltaic cell (1) as claimed in claim 4, characterized in that the alkali-metal barrier layer (24) is based on a dielectric material, especially one based on silicon nitrides, oxides or oxynitrides, or on aluminum nitrides, oxides or oxynitrides, used by themselves or as a mixture with zinc oxide, or based on mixed zinc tin oxide.

6. The photovoltaic cell (1) as claimed in claim 1, characterized in that the smoothing layer (22) has a resistivity ρ of between 5 mΩ·cm and 200 Ω·cm.

7. The photovoltaic cell (1) as claimed in claim 2, characterized in that the tie layer (23) has a resistivity ρ of between 5 mΩ·cm and 200 Ω·cm.

8. The photovoltaic cell (1) as claimed in claim 1, characterized in that it includes a coating based on a photovoltaic material (200), especially based on cadmium, above the electrode coating (100), on the side away from the substrate (10).

9. A substrate (10) coated with a thin-film multilayer for a photovoltaic cell (1) as claimed in claim 1, especially a substrate for architectural glazing, in particular a substrate for “toughenable” architectural glazing or architectural glazing “to be toughened”.

10. The use of a substrate coated with a thin-film multilayer for producing a faceplate substrate (10) of a photovoltaic cell (1), in particular a photovoltaic cell (1) as claimed in claim 1, said substrate having a transparent electrode coating (100) consisting of a thin-film multilayer comprising at least one transparent conductive layer, especially one based on zinc oxide, and at least one smoothing layer.

11. The use as claimed in claim 10, in which the substrate (10) having the electrode coating (100) is a substrate for architectural glazing, especially a substrate for “toughenable” architectural glazing or architectural glazing “to be toughened”.
